(19) United States
(12) Patent Application Publication
(10) Pub. No.: US 2005/0149823 A1
(43) Pub. Date: Jul. 7, 2005

(54) Apparatus and method for generating checksum

(75) Inventor: Min-jae Lee, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRIONICS CO., LTD.

(21) Appl. No.: 11/008,163

(22) Filed: Dec. 10, 2004

(30) Foreign Application Priority Data
Dec. 10, 2003 (KR) 2003-89354

(51) Int. Cl. H03M 13/00; G06F 11/10

(52) U.S. Cl. 714/758

(57) ABSTRACT

An apparatus and method for generating a checksum. The checksum generation method includes: determining whether or not an already calculated first checksum value is identical or similar to a second checksum value for which calculation is requested; if it is determined that the values are identical or similar, reading a difference value of the first checksum value and the second checksum value from a database; and by adding the read difference value to the first checksum value, generating the second checksum value. According to the method, when a checksum value identical or similar to an already calculated checksum value is to be calculated, the calculation is not performed again and instead, by adding only the difference value, a new checksum value is generated

### CROSS-REFERENCE TO RELATED APPLICATIONS

This application claims priority from Korean Patent Application No. 2003-89354, filed on Dec. 10, 2003, in the Korean Intellectual Property Office, the disclosure of which is incorporated herein in its entirety by reference.

### BACKGROUND OF THE INVENTION

1. Field of the Invention

The present invention relates to an apparatus and method for processing a packet, and more particularly, to an apparatus and method for generating a checksum for a packet.

2. Description of the Related Art

Conventional checksum methods, including a checksum method of an Internet control message protocol version 6 (ICMPv6) specified in Request for Comments (RFC) 2463, employs a method by which a checksum value is always calculated when the accuracy of a received packet is examined, or when the checksum field value of a packet to be transmitted is input, or when a checksum value is requested. However, since the checksum calculation requires computation of a large amount of data, it increases the load on a system and in the process for packet processing, acts as a main factor in the time expenditure.

### SUMMARY OF THE INVENTION

The present invention provides an apparatus and method by which when a checksum value identical or similar to a previously calculated checksum value is to be calculated, a new checksum value can be generated by adding only a difference value without performing a full calculation, and a packet processing apparatus and method enabling a packet to be efficiently processed by using the checksum calculation apparatus and method.

According to an aspect of the present invention, there is provided a checksum generation method including: determining whether or not an already calculated first checksum value is identical or similar to a second checksum value for which calculation is requested; if it is determined that the values are identical or similar, reading a difference value of the first checksum value and the second checksum value from a database; and by adding the read difference value to the first checksum value, generating the second checksum value.

According to another aspect of the present invention, there is provided a checksum generation apparatus including: a checksum selector which if the value of a predetermined field of a message to be output to the outside indicates that an already calculated checksum value and the checksum value of the message are identical or similar, outputs the value of the predetermined field; a difference value reader which reads a difference value corresponding to the value of the predetermined field output from the checksum selector, from a database and outputs the read difference value; and an adder which adds the difference value output from the difference value reader to the already calculated checksum value to generate the checksum value of the message.

According to still another aspect of the present invention, there is provided a packet processing method including: by adding a difference value of an already calculated first checksum value and a second checksum value identical or similar to the first checksum value, to the first checksum value, generating the second checksum value; and by using the generated second checksum value, completing a packet.

According to yet still another aspect of the present invention, there is provided a computer readable recording medium having embodied thereon a computer program for the checksum generation method.

According to a further aspect of the present invention, there is provided a computer readable recording medium having embodied thereon a computer program for the packet processing method.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of the structure of a packet processing apparatus according to a preferred embodiment of the present invention;

FIG. 2 is a diagram showing the format of an Internet protocol version 6 (IPv6);

FIG. 3 is a diagram showing fields in which data for calculating a checksum value are recorded;

FIG. 4 is a diagram showing an IPv6 packet including an echo request message and an IPv6 packet including an echo reply message;

FIG. 5 is a diagram of the structure of a checksum generation apparatus according to a preferred embodiment of the present invention;

FIG. 6 is a flowchart of the steps performed by a packet processing method according to a preferred embodiment of the present invention; and

FIG. 7 is a flowchart of the steps performed by a checksum generation method according to a preferred embodiment of the present invention.

### DETAILED DESCRIPTION OF THE INVENTION

The present invention will now be described more fully with reference to the accompanying drawings, in which exemplary embodiments of the invention are shown.

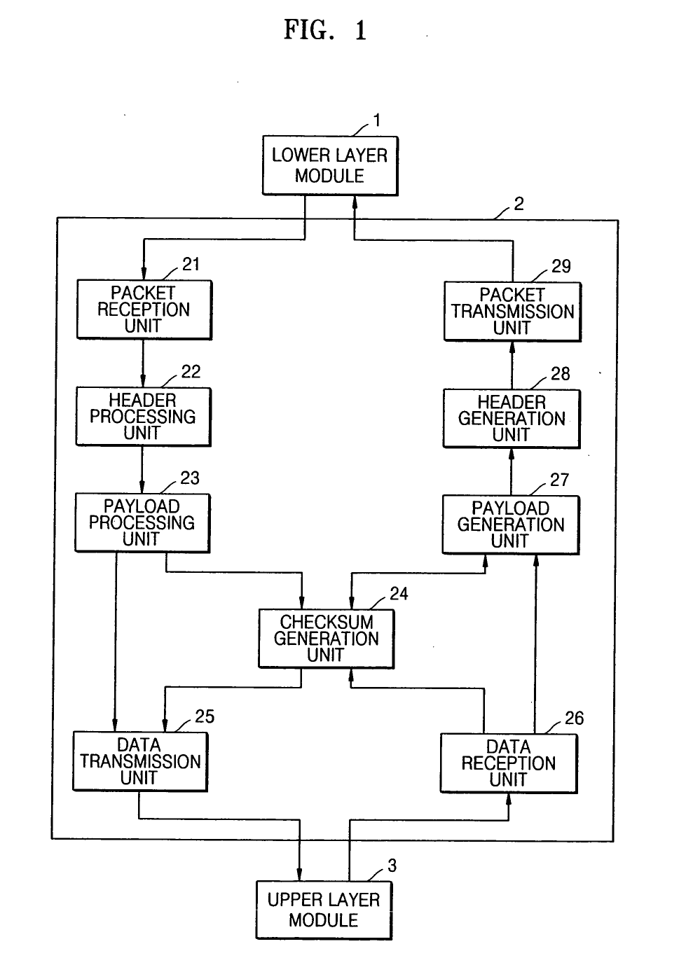

Referring to FIG. 1, a packet processing apparatus 2 according to an exemplary embodiment of the present invention includes a packet reception unit 21, a header processing unit 22, a payload processing unit 23, a checksum generation unit 24, a data transmission unit 25, a data reception unit 26, a payload generation unit 27, a header generation unit 28, and a packet transmission unit 29. The packet processing unit 2 is a kind of module existing between a lower layer module 1 and an upper layer module.

For example, if the lower layer module 1 is a link layer module implemented by a LAN interface, an Institute of Electrical and Electronics Engineers (IEEE) 1394 interface, a universal serial bus (USB) interface, and a wireless LAN (WLAN) interface, and the upper module 3 is an application layer module, then the packet processing apparatus 2 will be a module unifying an IP layer module and a transmission control protocol/user datagram protocol (TCP/UDP) layer module.

The packet reception unit 21 receives a first packet from the lower layer module 1. If the lower layer module 1 is a link layer module, then the first packet will be an IP packet. The IP packet may be an IPv4 packet or an IPv6 packet according to the version of the packet. Hereinafter, mainly the IPv6 packet will be used as an example for explanation.

The header processing unit 22 examines the values in the fields of the first header included in the received first packet, and by processing the first packet according to the examined result, extracts a first payload from the first packet.

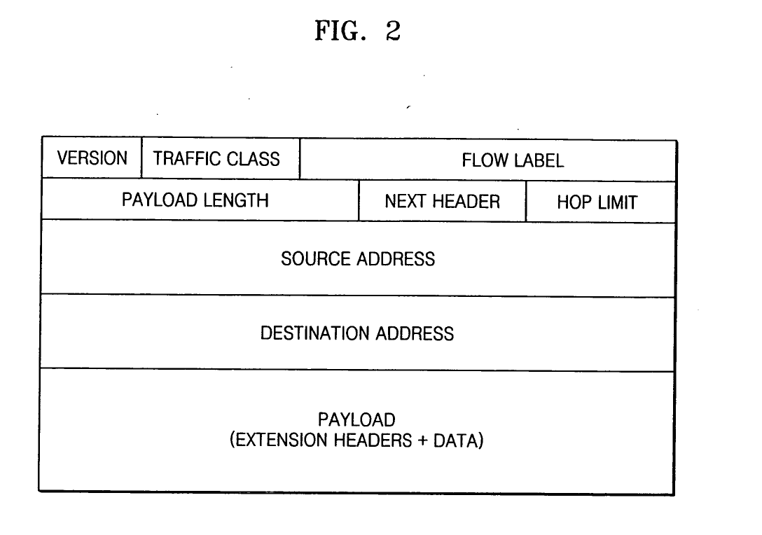

FIG. 2 is a diagram showing the format of an Internet protocol version 6 (IPv6).

Referring to FIG. 2, the IPv6 packet is formed with an IPv6 header and a payload. The IPv6 header includes a version field, a traffic class field, a flow label field, a payload length field, a next header field, a hop limit field, a source address field, and a destination address field.

If the first packet is an IPv6 packet, the header processing unit 22 examines the values of the shown fields of the IPv6 header, and when the value of each field is recognized after finishing the examination, performs processing requested by the value of each field. Since the IPv6 header has a fixed length of 40 bytes, if the part after the 40 bytes is extracted, this part becomes the payload. However, if the value of a next header field indicates that an extension header is attached, then, the part after the 40 bytes begins with the extension header. The IPv6 packet may not have or may have one or more extension headers. Hereinafter, assuming that the part excluding this extension header is a payload, the present invention will be explained. (In an IPv6 packet, the part excluding the header may be referred to uniformly as a payload, and in this case, the part excluding the extension header is referred to as upper data.)

When predetermined field values among the field values examined in the header processing unit 22 indicate that the extracted first payload is a first message, the payload processing unit 23 examines the values of fields of the extracted first payload, based on the format of the first message, and by processing the first payload, according to the examined result, extracts first data from the first payload. In the IPv6 header, if the value of the next header field is 2, it indicates an ICMP message, if 6, a TCP message (also referred to as a TCP packet), and if 17, a UDP message (also referred to as a UDP packet). Like an IP packet, a payload is also formed with a header and data according to the format of each message, and the payload processing unit 23 examines the values of fields of the first payload, that is, the values of fields of the header of each message, based on the format of the message, and if the value of each field is recognized after the examination is finished, performs processing requested by the value of each field. In this processing process, the first data that is to be transmitted to the upper layer module 3 is extracted.

When the value of a predetermined field indicates that the first payload is a first message having a first checksum value, the checksum generation unit 24 performs checksum calculation with data for calculating the checksum value of the first message.

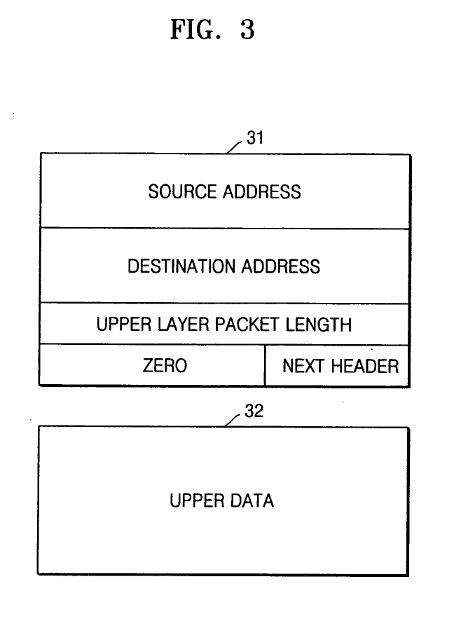

FIG. 3 is a diagram showing fields in which data for calculating a checksum value are recorded.

Referring to FIG. 3, the fields in which data for calculating a checksum value are recorded form a pseudo header 31 and upper data 32. The pseudo header 31 is formed with a source address field, a destination address field, an upper layer packet length field, a zero field, and a next header field. As described above, the upper data 32 indicates a payload excluding an extension header.

The pseudo header 31 is not an actually existing header, and is formed with fields extracted from an IPv6 header in order to calculate the checksum value of an ICMP message. This is newly adopted in the IPv6 standard in order to protect an ICMP message in a case where an error occurs in an IP header in the process of transmitting the IP packet. The checksum generation unit 24 obtains 1's complements of the values of the source address field, the destination address field, the upper layer packet length field, the zero field, the next header field, and the upper data, and then, adds all the complements, and by obtaining the 16-bit-1's complement of the added result, generates the checksum value of the first message.

If the result value of the checksum calculation performed in the checksum generation unit 24 is identical to the first checksum value, the data transmission unit 25 transmits the extracted first data to the upper layer module 3. If the result value of the checksum calculation is not identical to the first checksum value, the accuracy of the received first packet is not guaranteed and therefore, the first packet is discarded.

The data reception unit 26 receives second data from the upper layer module 3 which receives the first data transmitted by the data transmission unit 25. The upper layer module 3 receives the first data and performs jobs according to the received first data. Also, the upper layer module 3 generates the second data as the result of the jobs and transmits the generated second data to the packet processing apparatus 2.

If the value of a predetermined field included in the second data received by the data reception unit 26 indicates a second message having a checksum value identical or similar to the first checksum value, the checksum generation unit 27 generates a second checksum value that is the checksum value of the second message, by adding a predetermined difference value to the first checksum value. If the value of a predetermined field included in the second data indicates a third message having a checksum value different from the first checksum value, the checksum generation unit 27 performs checksum calculation with data for calculating the checksum value of the third message and generates the third checksum value that is the checksum value of the third message. An ICMP message can be an example of the second message, and a TCP message or a UDP message can be an example of the third message. Here, the second data is the result of jobs processed in the upper layer module 3, and mainly includes information on generation of a packet to be transmitted to another host through a network.

According to the present embodiment, in a process for processing a received packet, the presence of an error in the transmission process should be examined, and for this, in the same manner as in the conventional technology, a checksum value is calculated and compared with a checksum value recorded in a packet. However, since an error cannot occur inside a system in a process to generate a packet to be transmitted, checksum value calculation is not uniformly performed as in the conventional technology. Instead, if there is an already calculated first checksum value, a checksum value identical or similar to the first checksum value is obtained by only adding the difference value to the first checksum value. However, this assumes the data integrity inside the system. All conventional checksum methods also assume the data integrity inside a system.

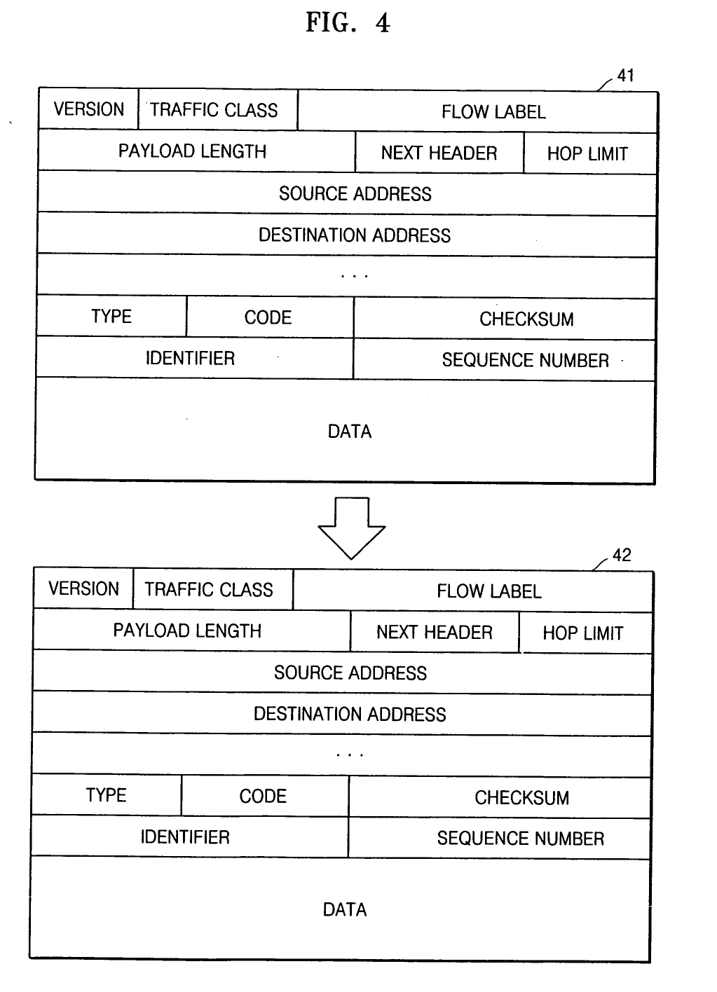

FIG. 4 is a diagram showing an IPv6 packet including an echo request message and an IPv6 packet including an echo reply message.

Referring to FIG. 4, the IPv6 packet 41 including an echo request message is formed with the IPv6 header, an extension header (only when this is disposed), and an echo request message shown in FIG. 2. The echo request message is formed with a type field, a code field, a checksum field, an identifier field, a sequence number field, and a data field. The IPv6 packet 42 including an echo reply message has the same fields. The echo request message and the echo reply message are a kind of ICMP message. If the value of the next header field of the IPv6 header (when there is an extension header, the value of a next header field of the last extension header) is 58 and the type of the ICMP message is 128, it indicates that the payload is an echo request message, and if the type is 129, the payload is an echo reply message.

The echo request message and the echo reply message are mainly used for ping. The ping is an application program using a TCP/IP protocol and checks whether an IP datagram can arrive at another host. The program performing the ping transmits an echo request message to a destination host and waits for whether or not there is a reply. That is, if the destination host is in operation, it will transmit an echo reply message, and if not in operation, will not transmit an echo reply message. Accordingly, depending on whether or not an echo reply message is returned, it can be examined whether or not the destination host is in operation.

Thus, since the echo request message and the echo reply message are used to examine only whether or not a destination host is in operation, the field values except the type field are identical. Accordingly, the total sum of the upper data 32 has a difference of 1. If 16 bit addition is performed for checksum calculation, the value that is a difference of 1 in an 8th bit changes into a difference of a hexadecimal value 100. Accordingly, the difference of total sums becomes a hexadecimal value of 100. Hereinafter, this is applied identically. Also, this is a case where the source host and the destination host are mutually exchanged, and since only the source address and the destination address are mutually exchanged, the total sums of values of the fields of the pseudo header 31 shown in FIG. 3 are identical.

If the first packet is an IP packet including an echo request message and there is no error in the process transmitting it through a network, the first checksum value and the second checksum value have a difference of 1. At this time, the checksum generation unit 24 adds 1 to the first checksum value and generates the second checksum value of an echo reply message.

The payload generation unit 27 generates a second payload corresponding to the second message including a checksum field in which the second checksum value generated in the checksum generation unit 24 is recorded.

For example, if the second message is an echo reply message, the payload generation unit 27 generates a second payload, corresponding to an echo reply message, and including a checksum field in which a second checksum value obtained by adding 1 to a first checksum value.

The header generation unit 28 generates a second header to be attached to the second payload generated in the payload generation unit 27, and completes the second packet including the generated second payload and the generated second header. For example, if the second message is an echo reply message, an IP packet including an echo reply message and an IP header is completed.

The packet transmission unit 29 transmits the second packet completed in the header generation unit 28, to the lower layer module 1. That is, the packet transmission unit 29 transmits the second packet completed in the header generation unit 28, to the link layer module (LAN interface, IEEE 1394 interface, USB interface, WLAN interface, and so on) that is the lower layer module 1.

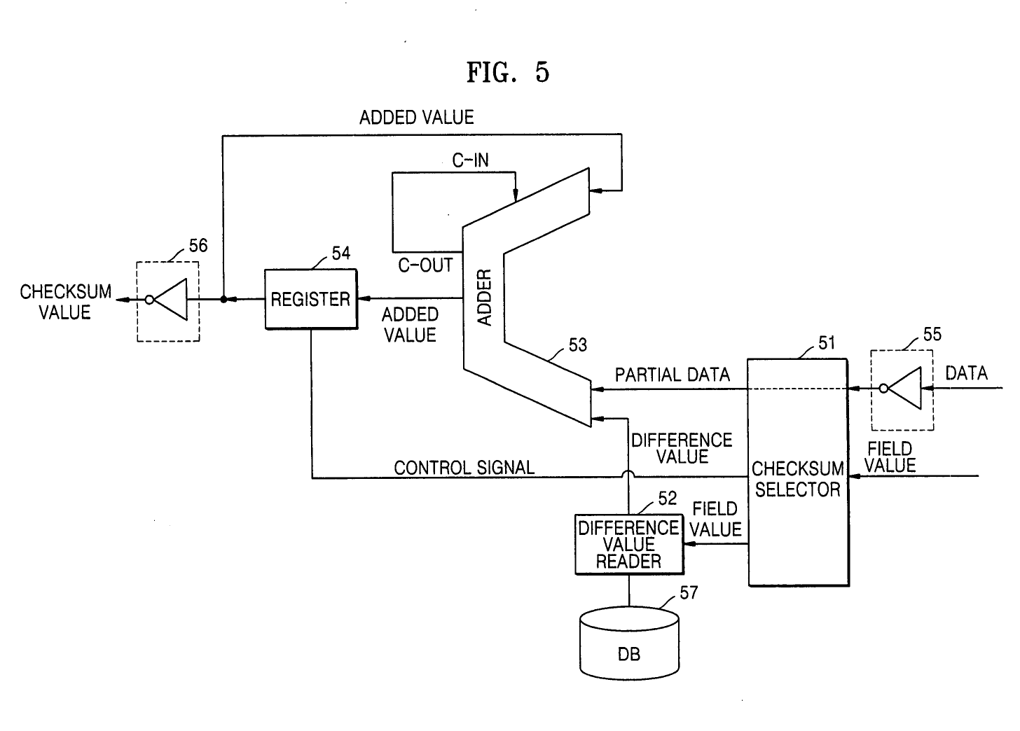

FIG. 5 is a diagram of the structure of a checksum generation apparatus according to a preferred embodiment of the present invention.

Referring to FIG. 5, the checksum generation apparatus includes a checksum selector 51, a difference value reader 52, an adder 53, a register 54, a first inverter 55, and a second inverter 56. The checksum generation apparatus corresponds to the checksum generation unit 24 shown in FIG. 1 and FIG. 5 can be regarded as a detailed diagram of the structure of the checksum generation unit 24.

The first inverter 55 generates data for calculating a checksum value of a predetermined message by obtaining the 1's complement of predetermined data. Here, the predetermined data will be the values of the fields of the pseudo header 31 and the upper data 32 shown in FIG. 3. When the message is an ICMP message, the sum of 1's complements of the ICMP message, which is the pseudo header 31 and the upper data 32, is obtained, and then by obtaining the 16-bit-1's complement of the sum, the checksum value is generated. Accordingly, the first inverter 55 as above is needed at the data reception end. However, in a case where 1's complement does not need to be obtained, it is not needed. The message is determined as a first message or a second message in the following procedure. Since in the case of the first message, checksum calculation is not performed again, the first inverter 55 is useful only for the second message.

If the value of a predetermined field is received, the checksum selector 51 outputs the value of the predetermined field to the difference value reader 52 when the received value of the predetermined field indicates a first message having a checksum value identical or similar to the first checksum value.

For example, if the first message is an echo reply message, the checksum selector 51 outputs the value of the next header field and the value of the type field of the ICMP message that indicate an echo reply message, to the difference value reader 52. At this time, the value of the next header field will be 58, and the type field value will be 129.

If the predetermined field values from the checksum selector 51 are received, the difference value reader 52 reads a difference value corresponding to the input predetermined field values database 57 and outputs the read difference value. For example, if the first message is an echo reply message, the difference value reader 52 receives the next header field value of 58, and the ICMP message type field value of 129. At this time, the difference value reader 52 searches the database 57, and reads a difference value recorded in a location corresponding to the next header field value of 58, and the ICMP message type field value of 129. In this location, 1 is recorded.

If the difference value from the difference value reader 52 is received, the adder 53 adds the received difference value to the first checksum value to generate the second checksum value that is the checksum value of the first message, and outputs the generated second checksum value to the register 54. For example, if the first message is an echo reply message, the message included in the received IP packet will be an echo request message, and the checksum value of this message becomes the first checksum value. The difference of this first checksum value and the second checksum value is 1. The first checksum value is a value that is already verified in the process of processing the received IP packet, and the second checksum value can be obtained, by only adding 1 to the first checksum value. Since the checksum generation apparatus according to the present embodiment is used both in the process for generating a first checksum value and the process for generating a second checksum value, the first checksum value is also a value output from the adder 53.

If the first checksum value from the adder 53 is input, the register 54 stores the input first checksum value. That is, the adder 53 adds the difference value received from the difference value reader 52, to the first checksum value stored in the register 54 to generate a second checksum value, and outputs the generated second checksum value again to the register 54. At this time, the register 54 stores the second checksum value input from the adder 53, which is a new checksum value. That is, the register is updated whenever a new checksum value is input.

The second inverter 56 obtains the 1's complement of the second checksum value and generates a final checksum value. If the first message is an ICMP message, sum of the 1's complements of the ICMP message is obtained, and then, the 16-bits-1's complement of the sum is obtained to generate a checksum value. Accordingly, the second inverter 56 as above is needed at the checksum output end. However, it will not be needed when the 1's complement does not need to be obtained.

When the value of the predetermined field indicates that the predetermined payload is a second message having a checksum value different from the first checksum value, the checksum selector 53 outputs a reset signal to the register 54, receives data for calculating the checksum value of the second message, and outputs the received data to the adder 53. For example, if the first message is a TCP message or a UDP message, the checksum selector 51 outputs the value of the next header field that is a field indicating a TCP message or UDP message, to the difference value reader 52. At this time, in case of a TCP message, the value of the next header field is 6 and in case of a UDP message, the value of the next header field is 17.

If a reset signal that is a kind of control signal is input from the checksum selector 51, the register 54 resets the stored first checksum value. Since the output end of the register 54 is connected to the input end of the adder 53, a value stored in the register 54 is input to the adder 53 and used as an augend. If the predetermined payload indicates a second message having a checksum value different from the first checksum value, this corresponds to a case where checksum calculation should be performed again, and accordingly, a value stored in the register 54 is reset. That is, a value stored in the register 54 is made to be 0.

The adder 53 receives first partial data included in data from the checksum selector 51, adds the input partial data to a value reset in the register 54 to generate a first partial checksum value, and outputs the generated first partial checksum value to the register 54, and if there is a carry occurring from the generated first partial checksum value, the carry is fed back to the adder 53. Since data for calculating the checksum value of a second message is generally bigger than the processing capacity of the adder 53, it should be divided into amounts that can be processed by the adder 53 and then be processed. For example, when a first message is an echo reply message, the sum of 16-bit-1's complements should be obtained, and accordingly, a two-input 16-bit adder should be used as the adder. In this case, since the adder 53 can receive a bit string of only 16 bits, data for calculating the checksum value of the second message should be divided into 16 bits and be processed. At this time, the first partial data becomes 16-bit data. However, for faster calculation, a plurality of adders can be disposed in parallel to perform checksum calculation. That is, when two 16-bit adders perform checksum calculation in parallel, 32-bit data can be processed at one time.

If the first partial checksum value from the adder 53 is input, the register 54 stores the input first partial checksum value and feeds the stored first partial checksum value back to the adder 53. As shown in the above description, the register 54 stores the value output from the adder 53, and according to an output signal that is a kind of control signal from the checksum selector 51, outputs the stored value to the adder 53. By doing so, the register 54 makes the calculation perform smoothly. The checksum selector 51 transmits an output signal to the register 54 when a currently stored value and a value to be added are input to the register 54.

If the first partial checksum value from the register 54 is fed back, the adder 53 receives an input of second partial data included in the data from the checksum selector 51. If a carry is not fed back, the adders 53 add the input second partial data to the first partial checksum value fed back, to generate a second partial checksum value, and if a carry is fed back, adds the input second partial data and the carry fed back to the first partial checksum value fed back, to generate a second partial checksum value. In an example of a two-input 16-bit adder, if 16-bit first partial data is added to 0, the 16-bit first partial data becomes the first partial checksum value. Again, 16-bit second partial data is added to the 16-bit first partial data fed back. Again, 16-bit third partial data is added to the sum of the 16-bit first partial data and the 16-bit second partial data fed back. If a carry occurs, the carry is fed back, and in the next addition, addition is performed including the carry fed back. This process is repeated for the entire data for calculating the checksum value of the second message such that a third checksum value that is the checksum value of the second message can be generated.

The second inverter 56 obtains the 1's complement of the third checksum value to generate a final checksum value. As described above, when the 1's complement does not need to be obtained, the inverter 56 is not needed.

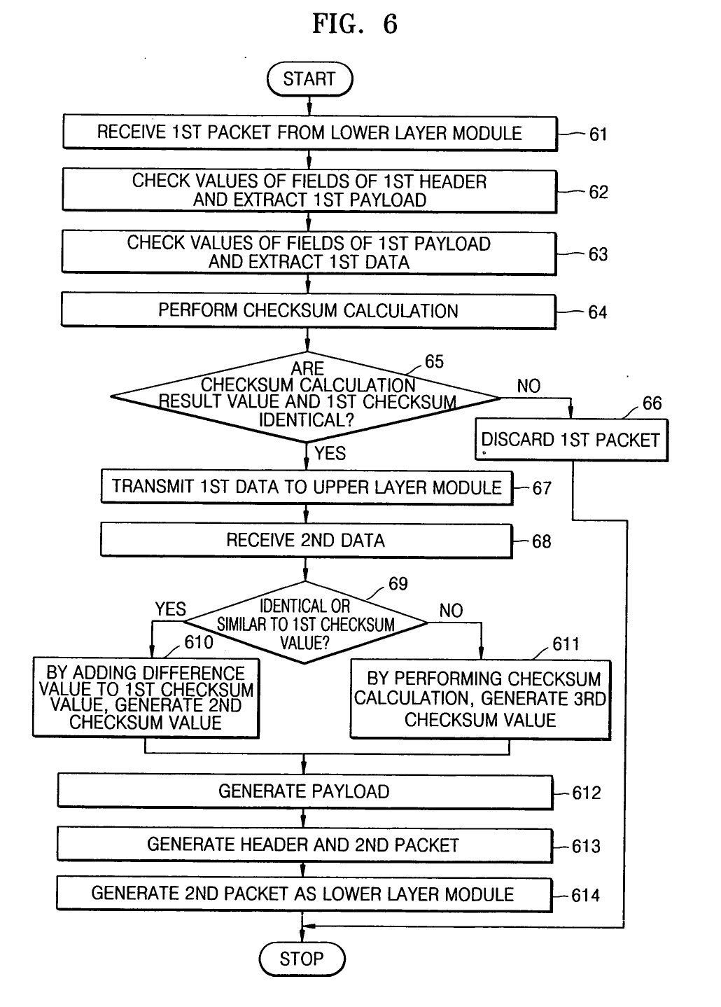

FIG. 6 is a flowchart of the steps performed by a packet processing method according to an exemplary embodiment of the present invention.

Referring to FIG. 6, the steps forming the packet processing method will now be explained.

A first packet from a lower layer module is received in step 61. Then, the values of fields of a first header included in the received first packet are examined and according to the examination result, the first is processed such that a first payload from the first packet is extracted in step 62. Then, if the value of a predetermined field among the examined field values indicates that the first payload is a first message, the values of fields of the first payload are examined based on the format of the first message, and according to the examined result, the first payload is processed such that first data is extracted from the first payload in step 63.

Next, if the value of a predetermined field indicates that the first payload is a first message having a first checksum value, checksum calculation is performed with data for calculating the checksum value of the first message in step 64. Then, if the result value of the performed checksum calculation and the first checksum value are identical in step 65, extracted first data is transmitted to the upper layer module in step 67. If the result value of the performed checksum calculation and the first checksum value are not identical in step 65, the first packet is discarded in step 66.

Next, second data from the upper layer module which receives the transmitted first data is received in step 68. Then, if the value of a predetermined field included in the received second data indicates a second message having a checksum value identical or similar to the first checksum value in step 69, a predetermined difference value is added to the first checksum value to generate a second checksum value that is the checksum value of the second message in step 610. Here, if the second message is an ICMP message, that is, if the second packet is an IPv6 packet, the predetermined field is the next header field, and the value of the next header field is 2, and when the value of the type field of the ICMP message indicates an echo reply message, the second checksum value is generated by adding 1 to the first checksum value. If the value of the predetermined field indicates a third message having a checksum value different from the first checksum value in step 69, checksum calculation is performed with data for calculating the checksum value of the third message such that the third checksum value which is the checksum value of the third message is generated in step 611. Here, if the third message is a TCP message or a UDP message, that is, if the second packet is an IPv6 packet, the predetermined field is the next header field, and the value of the next header field is 6 or 17, the checksum value is calculated again. Then, a second payload corresponding to the second message and including a checksum field in which the generated second checksum value is recorded is generated in step 612. Then, a second header to be attached to the generated second payload is generated and a second packet including the generated second payload and second header is completed in step 613. Then, the completed second packet is transmitted to the lower layer module in step 614.

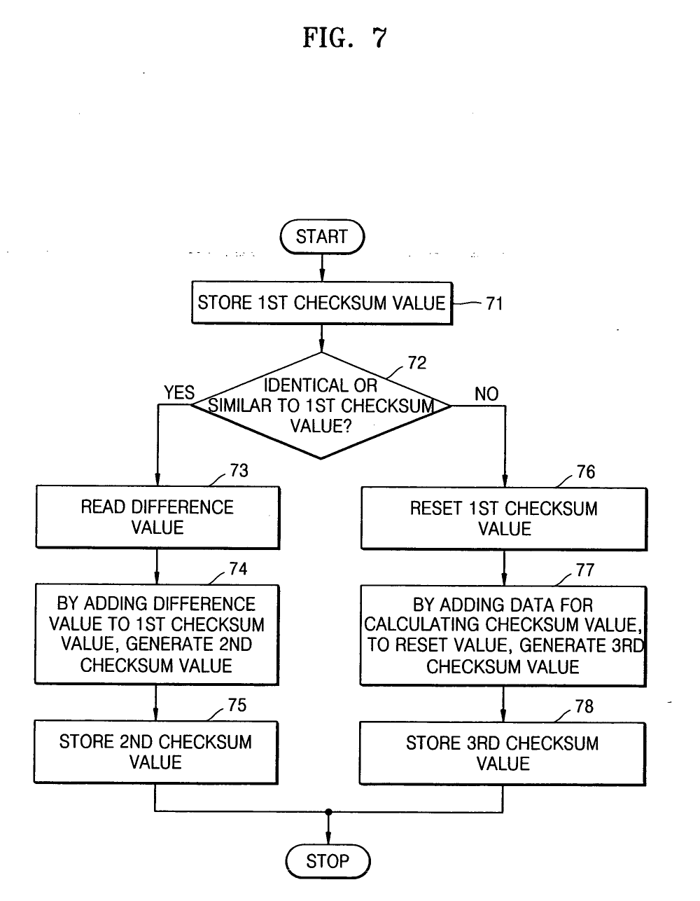

FIG. 7 is a flowchart of the steps performed by a checksum generation method according to an exemplary embodiment of the present invention.

Referring to FIG. 7, the steps of the checksum generation method will now be explained.

If a first checksum value is input, the input first checksum value is stored in step 71. Then, if the value of a predetermined field is received, and if the value of the received predetermined field indicates that a predetermined payload is a first message having a checksum value identical or similar to the first checksum value, the value of the predetermined field is output in step 72. Then, if the value of the output predetermined field is input, a difference value corresponding to the value of the input predetermined field is read and the read difference value is output in step 73. Then, if the output difference value is input, the input difference value is added to the first checksum value to generate a second checksum value that is the checksum value of the first message and the generated second checksum value is output in step 74. Then, if the output second checksum value is input, the input second checksum value is stored in step 75. Here, if the first message is an ICMP message, that is, if the predetermined field is the next header field, the value of the next header field is 58, and the value of the type field of the ICMP message indicates an echo reply message, that is, the value of the type field is 129, 1 is added to the first checksum value such that the second checksum value is generated.

If the value of a predetermined field indicates that a predetermined payload is a second message having a checksum value different from the first checksum value, a reset signal is output and data for calculating the checksum value of the second message is received and the received data is output in step 72.

If the second message is an ICMP message, the sum of the 1's complements of the pseudo header 31 shown in FIG. 3 and the upper data 32 that is an ICMP message is obtained, and by obtaining the 16-bit-1's complement of the sum, the checksum value is generated. Accordingly, a step for generating data for calculating the checksum value of the second message by obtaining the 1's complements of the pseudo header and the ICMP message is needed before the step 72. However, when the 1's complement does not need to be obtained, the step is not needed. Then, if the output reset signal is input, the stored first checksum value is reset in step 76. Then, the output data is input, and added to the reset value to generate a third checksum value that is the checksum value of the second message, and the generated third checksum value is output in step 77. More specifically, the first partial data included in data is input and added to the reset value such that the first partial checksum value is generated. The generated first partial checksum value is fed back, and if a carry occurs from the generated first partial checksum value, the carry is fed back. If the first partial checksum value is fed back, the second partial data included in the data is input.

If a carry is not fed back, the input second partial data is added to the first partial checksum value fed back such that the second partial checksum value is generated, and if a carry is fed back, the input second partial data and the carry fed back are added to the first partial checksum value fed back such that the second partial checksum value is generated. The process is repeatedly performed for the remaining data in addition to the first partial data and the second partial data, such that the third checksum value is generated. Here, if the second message is a TCP message or a UDP message, that is, if the predetermined field is the next header field, and the value of the next header field is 6 or 17, the check value calculation is performed again.

Next, if a final checksum value is generated by obtaining the 1's complement, a step for generating a final checksum value by obtaining the 1's complement of the second or third checksum value is needed.

The embodiments of the present invention can be written as computer programs and can be implemented in general-use digital computers that execute the programs using a computer readable recording medium.

Also, the data structure used in the embodiments of the present invention described above can be recorded on a computer readable recording medium through a variety of ways.

Examples of the computer readable recording medium include magnetic storage media (e.g., ROM, floppy disks, hard disks, etc.), optical recording media (e.g., CD-ROMs, or DVDs), and storage media such as carrier waves (e.g., transmission through the Internet).

While the present invention has been particularly shown and described with reference to exemplary embodiments thereof, it will be understood by those of ordinary skill in the art that various changes in form and details may be made therein without departing from the spirit and scope of the present invention as defined by the following claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

According to the present invention, when a checksum value identical or similar to an already calculated checksum value is to be calculated, the calculation is not performed again and instead, by adding only the difference value, a new checksum value is generated such that load to a system due to the checksum calculation and the time taken for the calculation can be greatly reduced.

In particular, the present invention can be more usefully applied to a case where an echo request message is received and an echo reply message is transmitted. For example, by applying an online game using a ping function using an echo request message and an echo reply message, the performance of a system driving the online game can be improved.

1. A checksum generation method comprising:
determining whether or not an already calculated first checksum value is identical or similar to a second checksum value for which calculation is requested;
if it is determined that the values are identical or similar, reading a difference value of the first checksum value and the second checksum value from a database; and
by adding the read difference value to the first checksum value, generating the second checksum value.

2. The method of claim 1, wherein in determining whether or not an already calculated first checksum value is identical or similar to a second checksum value, determination is performed based on the value of a next header field of an Internet Protocol version 6 (IPv6).

3. The method of claim 2, wherein in determining whether or not an already calculated first checksum value is identical or similar to a second checksum value, if the next header field value indicates an Internet control message protocol (ICMP) message and the value of the type field of the ICMP message indicates an echo reply message, it is determined that the values are similar.

4. The method of claim 2, where in determining whether or not an already calculated first checksum value is identical or similar to a second checksum value, if the value of the next header field indicates a transmission control protocol (TCP) message or a user datagram protocol (UDP) message, it is determined that the values are not identical or similar.

5. The method of claim 1, further comprising:
if it is determined that the values are not identical or similar in determining whether or not an already calculated first checksum value is identical or similar to a second checksum value, receiving data for calculating the second checksum value; and
by using the received data, calculating the second checksum value.

6. A checksum generation apparatus comprising:
a checksum selector which if the value of a predetermined field of a message to be output to the outside indicates that an already calculated checksum value and the checksum value of the message are identical or similar, outputs the value of the predetermined field;
a difference value reader which reads a difference value corresponding to the value of the predetermined field output from the checksum selector, from a database and outputs the read difference value; and
an adder which adds the difference value output from the difference value reader to the already calculated checksum value to generate the checksum value of the message.

7. The apparatus of claim 6, wherein the predetermined field is a next header field of an IPv6 header.

8. The apparatus of claim 7, wherein if the value of the next header field of the message indicates an ICMP message, the checksum selector outputs the value of the next header field and the value of the type field of the ICMP message.

9. The apparatus of claim 6, further comprising:
a register which stores the already calculated checksum value, wherein the adder generates the checksum value of the message by adding the checksum value stored in the register, and outputs the generated checksum value to the register.

10. The apparatus of claim 9, wherein if the value of the predetermined field indicates that the already calculated checksum value and the checksum value of the message are not identical or similar, the checksum selector outputs a reset signal to the register, receives data for calculating the checksum value of the message, and outputs the data to the adder, and if the reset signal is received, the register resets the stored checksum value, and the adder receives the data, and adds the data to the value reset in the register such that the checksum value of the message is generated.

11. A packet processing method comprising:
by adding a difference value of an already calculated first checksum value and a second checksum value identical or similar to the first checksum value, to the first checksum value, generating the second checksum value; and
by using the generated second checksum value, completing a packet.

12. The method of claim 11, further comprising:
by performing checksum calculation of data for calculating a third checksum value which is not identical or similar to the first checksum value, generating the third checksum value.

13. The method of claim 11, wherein in generating the second checksum value, the second checksum value is generated if the value of the next header field of an IPv6 header indicates that the first checksum value and the second checksum value are identical or similar.

14. The method of claim 11, wherein completing the packet comprises:
generating a payload including a checksum field in which the generated second checksum value is recorded; and
generating a header to be attached to the generated payload and completing a packet including the generated payload and the generated header.

15. The method of claim 11, further comprising:
by using data included in a packet received from a lower layer module, performing checksum calculation; and
if the result value of the performed checksum calculation is identical to the first checksum value included in the received packet, transmitting a payload extracted from the received packet, to an upper layer module,
wherein in generating the second checksum value, the second checksum value of a payload transmitted by the upper layer module which received the transmitted payload is generated.

16. A computer readable recording medium having embodied thereon a computer program for a checksum generation method,
wherein the method comprises:
determining whether or not an already calculated first checksum value is identical or similar to a second checksum value for which calculation is requested;
if it is determined that the values are identical or similar, reading a difference value of the first checksum value and the second checksum value from a database;
and by adding the read difference value to the first checksum value, generating the second checksum value.

17. A computer readable recording medium having embodied thereon a computer program for a packet processing method,
wherein the method comprises:
by adding a difference value of an already calculated first checksum value and a second checksum value identical or similar to the first checksum value, to the first checksum value, generating the second checksum value; and
by using the generated second checksum value, completing a packet.
